(19) United States
(12) Patent Application Publication
(10) Pub. No.: US 2026/0136929 A1
(43) Pub. Date: May 14, 2026

(54) CHIP PACKAGE WITH METAL THERMAL INTERFACE MATERIAL RETAINER

(71) Applicant: Advanced Micro Devices, Inc., Santa Clara, CA (US)

(72) Inventors: Manish DUBEY, Austin, TX (US); Deepak Vasant KULKARNI, Austin, TX (US); Kaushik MYSORE, Austin, TX (US); Priyal SHAH, Bangalore (IN)

(21) Appl. No.: 18/946,607

(22) Filed: Nov. 13, 2024

(51) Int. Cl. H01L 23/00; H01L 23/31; H01L 23/373; H01L 25/16

(52) U.S. Cl. CPC H10W 40/255; H10W 74/114; H10W 90/00; H10W 72/07236; H10W 72/073; H10W 72/07336; H10W 72/323; H10W 72/352; H10W 72/387; H10W 90/724; H10W 90/734

(57) ABSTRACT

Chip packages having thermal interface retaining structures and methods for fabricating the same are disclosed herein. In one example, a chip package including a substrate, an integrated circuit (IC) die, a first metal thermal interface material (MTIM), a lid, and a retaining structure. The substrate includes a bottom surface facing a top surface of the substrate. The first MTIM is disposed on a top surface of the IC die. The lid is disposed over the IC die and has a bottom side contacting the first MTIM. The thermal interface retaining structure is disposed outwardly of the first MTIM and captures the first MTIM on the top surface of the IC die.

### TECHNICAL FIELD

Embodiments of the present disclosure generally relate to chip packages and techniques for manufacturing the same. In particular, to a lidded chip package having one or more structures arranged to retain metal thermal interface material.

### BACKGROUND

Electronic devices, such as tablets, computers, server, in-door telecom, out-door telecom, industrial computers, high performance computing data centers, copiers, digital cameras, smart phones, control systems and automated teller machines, among others, often employ electronic components which leverage chip package assemblies for increased functionality and higher component density. Conventional chip package assemblies include one or more stacked components such as integrated circuit (IC) dies, through-silicon-via (TSV) interposer, and a package substrate, with the chip package itself stacked on a printed circuit board (PCB). The IC dies may include memory, logic, MEMS, RF or other IC device.

With progressive increase in package body size for high-performance compute and machine learning packages, the amount of package warpage has undesirably also increase. The amount of heat produced by these high-performance packages is also increasing, which requires efficient thermal solutions in order to effectively dissipate the generated heat. At the same time, there is a need to shrink ball grid array (BGA) pitches to further enable high speed signaling. However, larger packages with high warpages and tighter BGA pitches present significant challenges as such packages impose a very high risk of yield loss during surface mounting to PCBs. Moreover, effectively testing test packages having large body sizes when excessive warpage aggravated b inefficient heat dissipation also presents significant challenges.

Therefore, a need exists for an improved chip package.

### SUMMARY

Chip packages having thermal interface retaining structures and methods for fabricating the same are disclosed herein. In one example, a chip package including a substrate, an integrated circuit (IC) die, a first metal thermal interface material (MTIM), a lid, and a retaining structure. The substrate includes a bottom surface facing a top surface of the substrate. The first MTIM is disposed on a top surface of the IC die. The lid is disposed over the IC die and has a bottom side contacting the first MTIM. The retaining structure is disposed outwardly of the first MTIM and captures the first MTIM on the top surface of the IC die.

In one example, the retaining structure is a second MTIM having a melting point higher than a melting point of the first MTIM.

In another example, the retaining structure has a melting point of the second MTIM is greater than a ball grid array (BGA) reflow temperature.

In another example, the retaining structure has a melting point that is greater than about 240 degrees Celsius.

The retaining structure may be disposed at least partially on the top surface of the IC die; on a pre-substrate mounting mold material disposed on at least one sidewall of the IC die, the pre-substrate mounting mold material having a top surface substantially coplanar with the top surface of the IC die, wherein the second MTIM is disposed at least partially on the top surface of the pre-substrate mounting mold material; or on a post-substrate mounting mold material disposed on a top surface of the substrate adjacent to at least one sidewall of the IC die, the post-substrate mounting mold material having a top surface substantially coplanar with the top surface of the IC die, wherein the second MTIM is disposed at least partially on the top surface of the first the post-substrate mounting mold material.

In still another examples, the retaining structure is an adhesive or a permeable metal material. The permeable metal material may be a metal foam, a metal mesh, a metal wool, and the like.

In another examples, the retaining structure is a tin-based material.

In still other examples, the first MTIM is gallium, gallium-based alloy, indium or indium alloy.

In another example, a method for fabricating a chip package is provided. The method includes: mounting a lid over an integrated circuit (IC) die disposed on a substrate to form a lidded chip package; heating the lidded chip package to a first temperature, the first temperature above a melting point of a first metal thermal interface material disposed in contact with a top of the IC die and a bottom side of the lid and below a melting point of a second metal thermal interface material disposed around the first metal thermal interface material, wherein while at the first temperature, outgas generated by the first metal thermal interface material is able to flow across at least one side of the second metal thermal interface material; heating the lidded chip package to a second temperature above the melting point of the second metal thermal interface material, wherein after being heated to the second temperature, the second metal thermal interface material forming a gas seal around the first metal thermal interface material.

In another example of a method for fabricating a chip package, the method includes: mounting a lid over an integrated circuit (IC) die disposed on a substrate to form a lidded chip package; heating the lidded chip package to a first temperature, the first temperature above a melting point of a first metal thermal interface material disposed in contact with a top of the IC die and a bottom side of the lid, the second metal thermal interface material bounded on at least one side by a thermal interface retaining structure, wherein while at the first temperature, outgas generated by the first metal thermal interface material is able to flow through the thermal interface retaining structure.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional schematic view of one example of a lidded integrated chip package having a metal thermal interface material (MTIM) surrounded by a MTIM retainer.

FIG. 2A through FIG. 2E are partial sectional views of the chip package of FIG. 1 illustrating different locations of the MTIM retainer.

FIG. 3A is a schematic top view of the MTIM retainer surrounding the MTIM.

FIGS. 3B-3C are top views of alternative configurations of vents formed through the MTIM retainer.

FIGS. 3D and 3E are partial sectional views of the chip package taken along section lines 3D - - 3D and 3E - - 3E of FIG. 3C.

FIG. 4A and FIG. 4B depict the flow of gas outgassed from MTIM across the MTIM retainer during the initial fabrication stages of the chip package.

FIGS. 5A-5C depict various alternative examples of a MTIM retainer.

FIGS. 6A and 6B are schematic diagrams of one example of how the MTIM retainer depicted in FIG. 5C having the laminated layers may be fabricated.

FIG. 7A-7C are partial sectional views of a chip package having a lid that includes a pad configured enhance the functionality of the MTIM retainer.

FIG. 8A-8C are partial sectional views of a chip package having a lid that includes a gutter configured enhance the functionality of the MTIM retainer.

FIG. 9A-9C are partial sectional views of a chip package having a lid that includes a recess configured enhance the functionality of the MTIM retainer.

FIG. 10 is a flow diagram of one example of a method for forming a lidded chip package.

FIG. 11 is a flow diagram of another example of a method for forming a lidded chip package.

FIG. 12 is a flow diagram of another example of a method for forming a lidded chip package.

FIGS. 13A-13F are schematic side views of a chip package in different stages of fabrication.

To facilitate understanding, identical reference numerals have been used, where possible, to designate identical elements that are common to the figures. It is contemplated that elements of one embodiment may be beneficially incorporated in other embodiments.

### DETAILED DESCRIPTION

Embodiments of the disclosure generally provide chip packages and methods for fabricating the same that leverage retaining structures to retain metal thermal interface material (MTIM) in a desired location, thus improving performance and reliability. The novel chip package includes a picture frame shaped retaining structure disposed around an edge of an integrated circuit (IC) die to contain the MTIM on top of the IC die, and to significantly prevent pump-out of the MTIM upon securing a lid to the chip package and/or during ball grid array (BGA) during fabrication. In one example, the material comprising the retaining structure is selected to establish a clear thermal melting hierarchy, providing flux escape (degassing) during the initial MTIM melting and MTIM pump-out is prevented during BGA and subsequent reflow/process steps. In other examples, the material comprising the retaining structure is selected to allow degassing of the MTIM while still retaining the MTIM its desired location over the IC die. In still other examples, the material selection of retaining structure is simply selected to provide a physical barrier that substantially reduces or even eliminates pump-out of the MTIM from between the IC die and the lid.

The innovative approach, material selection, and fabrication process enables lidded chip packages to have improved thermal performance, especially for high performance compute products where the power consumption is approaching and exceeding 1000 Watts. Thus, the MTIM retaining structures promote good heat transfer, along with robust and reliable computing performance. It is to be understood that retaining structures may also be utilized to retain other TIM materials that are not metal based.

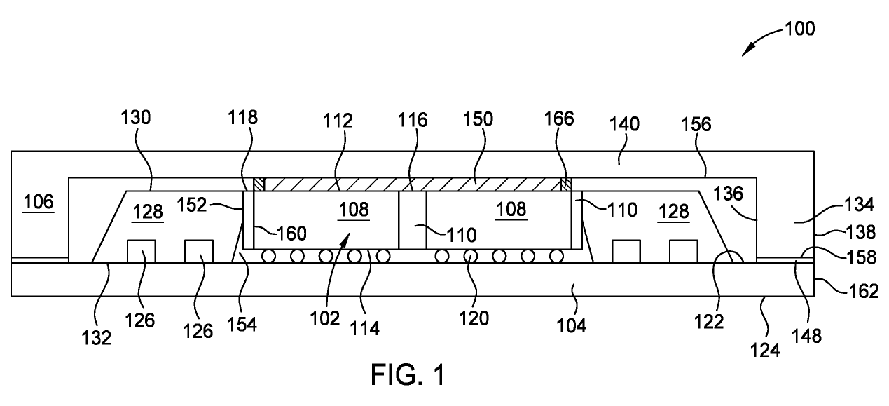

Turning now to FIG. 1, a schematic sectional view of a lidded integrated circuit (IC) chip package 100 is illustrated. The chip package 100 includes a substrate 104, an integrated circuit (IC) die complex 102, and a lid 106. The chip package 100 may optionally include a spacer 128, as later described below. A metal thermal interface material (MTIM) 150 is disposed between the lid 106 and at least one IC die 108 of the IC die complex 102 to promote heat transfer between the IC die 108 and the lid 106 of the chip package 100. The chip package 100 also includes a metal thermal interface material (MTIM) retainer 166 that is disposed around the MTIM 150, thus keeping the MTIM 150 desirably between the between the IC die 108 and the lid 106, particularly during solder reflow processes. Additionally, some examples of MTIM retainer 166 are configured to allow degassing of the MTIM 150 during the initial stages of fabrication, advantageously reducing occurrences of voids that could inhibit the effectiveness of heat transfer between the IC die 108 and the lid 106.

Describing first an IC die complex 102, the IC die complex 102 is mechanically connected to the substrate 104. The substrate 104 may be a package substrate as shown in FIG. 1, or be a combination of an interposer mounted on a package substrate. The IC die complex 102 generally includes at least one or more integrated circuit (IC) dies 108. Although two IC dies 108 are illustrated in FIG. 1, one to as many IC dies 108 that can fit on the substrate 104 may be utilized. The IC dies 108 of the IC die complex 102 may be surrounded by a mold compound 110. The mold compound 110 generally provides structural rigidity to the assembly of memory dies 108 comprising the IC die complex 102. The mold compound 110 is generally a polymer, such as epoxy. A portion of the mold compound 110 disposed outward of the sidewalls 160 of the IC dies 108 is referred to as a margin 118 of the mold compound 110. The laterally outer surface of the margin 118 defines an outer sidewall 152 of the IC die complex 102.

As discuss above, the compute die complex 102 generally includes at least one IC die 108. The compute die complex 102 may also include an optional active interposer on which the one or more IC dies 108 are mounted. In the example depicted in FIG. 1, two IC dies 108 are shown mounted side by side on the substrate 104. Alternatively or in addition to what is shown in FIG. 1, one or more other IC dies 108 may be stacked on one or more of IC dies 108 illustrated in FIG. 1.

Each IC die 108 includes functional circuitry. The functional circuitry of each IC die 108 in a common compute die complex 102 may be the same or different. In one example, at least one or both of the first IC die 108 and the second IC die 108 include central processing unit (CPU) cores. As such, the first and second IC dies 108 containing CPU cores may be referred to as a CPU die or CPU chiplet. The functional circuitry of the first and second IC dies 108 may also include System Management Unit (SMU). The SMU is circuitry configured to monitor thermal and power conditions and adjust power and cooling to keep the dies 108 functioning as within specifications. The functional circuitry of the first and second IC dies 108 may also include Dynamic Function eXchange (DFX) Controller IP circuitry. The DFX circuitry provides management of hardware or software trigger events. For example, the DFX circuitry may pull partial bitstreams from memory and delivers them to an internal configuration access port (ICAP). The DFX circuitry also assists with logical decoupling and startup events, customizable per Reconfigurable Partition.

In another example, the functional circuitry of at least one or both of the first IC die 108 and the second IC die 108 include accelerated compute cores. As such, each of the first and second IC dies 108 containing accelerated compute cores may be referred to as an accelerator die or accelerator chiplet. The first and second IC dies 108 containing accelerated compute cores may also be referred to as a graphic processing unit (GPU) die or GPU chiplet. The accelerated compute cores contained in the functional circuitry of the first and second IC dies 108 generally includes math engine circuitry. The math engine circuitry is generally designed for task specific computing, such as used data center computing, high performance computing and AI/ML computing. Along with the accelerated compute cores, functional circuitry of the first IC die 108 and the second IC die 108 may also include SMU circuitry and DFX circuitry.

In other examples, the functional circuitry the first IC die 108 and the second IC die 108 are different. For example, the first IC die 108 may include accelerated compute cores, while the second IC die 108 includes CPU cores. One or more compute dies, when present in the compute stack 102, may include CPU cores and/or an accelerated compute cores. In other examples, the first IC die 108 may include CPU and/or accelerated compute cores, while the second IC die 108 may be one of a stack of memory dies containing memory circuitry, such as to form a high bandwidth memory (HBM) device.

The functional circuitries the first IC die 108 and the second IC die 108 terminate at contact pads (not shown) exposed on a bottom surface 114 of each IC die 108. The contact pads exposed on the bottom surface 114 of each IC die 108 are electrically and mechanically coupled contact pads exposed on a top surface 122 of the substrate 104 by solder interconnects 120. The solder interconnects 120 may be microbumps, C4bumps, or other suitable connection that mechanically and electrically connects the routing of the substrate 104 to the functional circuitries of the IC dies 108 of the IC die complex 102. Stated differently, the solder interconnects 120 coupled the IC die complex 102 to the top surface 122 of the substrate 104.

Each IC die 108 of the IC die complex 102 also includes a top surface 112. The mold compound 110 encapsulating the IC dies 108 also includes a top surface 116. The top surfaces 112, 116 may be made substantially coplanar, for example, by grinding, milling, etching or other suitable technique.

Underfill 154 is disposed in the interstitial spaces between the bottom surface 114 of the IC dies 108 and the top surface 122 of the substrate 104, thereby providing structural rigidity to the chip package 100. The underfill 154 also surrounds and protects the solder interconnects 120. The underfill 154 may be an epoxy or other suitable material. The underfill 154 generally contacts the top surface 122 of the substrate 104 and also the outer sidewall 152 of the IC die complex 102. In the example depicted in FIG. 1, the underfill 154 extends partially up the outer sidewall 152 of the IC die complex 102, leaving an upper portion of the outer sidewall 152 exposed (i.e., free from underfill 154).

The substrate 104 may also include a plurality of surface mounted components 126. The surface mounted components 126 are coupled to functional circuitry of the IC dies 108 through the routing formed in the substrate 104. The surface mounted components may be integrated passive devices (IPDs), such as capacitors, inductors, and resistors, among others. In one example, the surface mounted components are capacitors. In addition or alternatively, some or all of the surface mounted components may be located as IPDs in other locations of the chip package 100. In the example depicted in FIG. 1, the surface mounted components 126 are in the form of capacitors mounted to the substrate 104 outward of the outer sidewall 152 of the IC die complex 102 and inward of the lid 106. The surface mounted components 126 may also be mounted to the substrate 104 outward of the underfill 154.

The optional spacer 128, when present, is formed or otherwise disposed on substrate 104 outward of the IC die complex 102. The spacer 128 is comprised of a polymeric material, such as a mold compound. In one example, the spacer 128 is formed from an epoxy. The spacer 128 is generally disposed outward of, and surrounds the IC die complex 102.

The spacer 128 has a top surface 130 and a bottom surface 132. The bottom surface 132 of the spacer 128 is disposed on the top surface 122 of the substrate 104. In one example, the spacer 128 encapsulates some or all of the surface mounted components 126 disposed on the top surface 122 of the substrate 104. The spacer 128 may touch or alternatively be spaced from the outer sidewall 152 of the IC die complex 102. In the example depicted in FIG. 1, the spacer 128 is in contact with at least the upper portion of the outer sidewall 152 of the IC die complex 102. The spacer 128 may also be in contact with the underfill 154.

The top surface 130 of the spacer 128 may be parallel or disposed at an acute angle with the top surface 122 of the substrate 104. The top surface 130 of the spacer 128 may be disposed at the same or different elevation as the top surface 112 of the IC die 108/IC die complex 102. In the example depicted in FIG. 1, the top surface 130 of the spacer 128 is substantially coplanar with the top surface 112 of the IC die 108/IC die complex 102.

The lid 106 is generally coupled to the chip package 100 over the IC die complex 102. The lid 106 includes a ring base 134 and a roof 140. The ring base 134 and the roof 140 may be made from separate or a single mass of material. The ring base 134 and the roof 140 is generally fabricated from a material having a high coefficient of heat transfer, such as a metal. In one example, the ring base 134 and the roof 140 are fabricated from stainless steel, aluminum, copper, nickel coated copper, metal composites, or other suitable material.

The ring base 134 has a bottom surface 158, an inner wall 136 and an outer wall 138. The bottom surface 158 of the ring base 134 is disposed on the top surface 122 of the substrate 104. The inner wall 136 of the ring base 134 faces the IC die complex 102 and spacer 128. In the example depicted in FIG. 1, the inner wall 136 of the ring base 134 is spaced from the outer edge of the spacer 128. The outer wall 138 of the ring base 134 is disposed at or near a peripheral edge 162 of the substrate 104.

The roof 140 extends from the inner wall 136 of the ring base 134 inward over the IC die complex 102. The roof 140 is generally spaced above the bottom surface 158 of the ring base 134 and the top surface 122 of the substrate 104. The roof 140 includes a bottom surface 156 that faces the IC dies 108 of the chip complex 102. The bottom surface 156 of the roof 140 is generally parallel with the top surface 112 of the IC dies 108, and in one example, the bottom surface 156 of the roof 140 is also parallel with the top surface 122 of the substrate 104.

As stated above, the lid 106 is generally coupled to the chip package 100 outward of the IC die complex 102. The lid 106 is coupled to the top surface 122 of the substrate 104 at or near the peripheral edge 162 of the substrate 104. The lid 106 may be coupled to the top surface 122 of the substrate 104 by any suitable technique, such as bonding, screwing, and clamping. In the example depicted in FIG. 1, the bottom surface 158 of the ring base 134 is secured to the top surface 122 of the substrate 104 by an adhesive 148. Without limitation, the adhesive 148 may be dispensed-in-place, configured in strips, or be die cut. The adhesive 148 may be an epoxy or other suitable bonding material. In one example, the adhesive 148 is polymer based or silica based.

As discussed above, the MTIM 150 is disposed in contact with the top surface 112 of the IC die 108 and the bottom surface 156 of the roof 140 to promote heat transfer from the IC die 108 to the lid 106. In one example, the MTIM 150 is gallium, gallium-based alloy, indium or indium alloy, or other suitable metal or metal alloy. The MTIM 150 is generally heated above it’s melting point as part of the chip package fabrication process aft the lid 106 has been installed to remove trapped gases that might become voids that disrupt the efficiency and uniformity of heat transfer between the IC die 108 and the lid 106.

The MTIM retainer 166 is generally disposed around the MTIM 150 to keep the MTIM 150 desirably between the between the IC die 108 and the lid 106. In one example, the MTIM retainer 166 is a second metal thermal interface material (relative to the first MTIM 150) that has a melting temperature greater than a melting temperature of the MTIM 150. In one example, the melting temperature of the MTIM 150 is 160 degrees Celsius. The melting point of the MTIM retainer 166 comprised of the second MTIM is greater than a ball grid array (BGA) reflow temperature, which is generally around 240 degrees Celsius. In another example, the melting point of the MTIM retainer 166 comprised of the second MTIM is greater than about 240 degrees Celsius, such as greater than about 250 degrees Celsius. In still another example, the second MTIM comprising of the MTIM retainer 166 is a solder-based TIM, such as tin and the like.

In another example, the MTIM retainer 166 is comprised of an adhesive. The adhesive has a service temperature greater than about 240 degrees Celsius. The adhesive may be comprised of a polymer-based or silica-based adhesive, such as but not limited to polydimethylsiloxane adhesive with thermally conductive fillers, aluminum filled one-part epoxy (i.e., Soctch-Weld^{TM} EW3010), semi-flowable heat curable silicone adhesive, among others. The adhesive, circumscribing the MTIM 150 generally blocks the MTIM 150 from flowing out from the space between the lid 106 and the chip complex 102. In examples wherein the MTIM retainer 166 is an adhesive, the additional attachment point of the lid 102 to the chip package 100 further increases the rigidity and resistance of the chip package to warping, thus increasing the reliability, performance, and service life of the chip package 100.

In still another example, the MTIM retainer 166 is comprised of a permeable metal material. The permeable metal material allows the MTIM 150 to outgas through the MTIM retainer 166 during fabrication of the chip package 100, such that essentially no voids are present in the space between the lid 106 and the chip complex 102 that is filled by the MTIM 150. In one example, the permeable metal material is one or more of a metal foam, a metal mesh, a metal wool, and the like. In a specific example, the MTIM retainer 166 is fabricated from copper, such as copper wool, copper mesh, copper foam and the like.

In the example depicted in FIG. 1, the MTIM retainer 166 contacts at least a portion of the top surface 112 of the IC die 108 that closest the margin 118, or closest the sidewall 160 of the IC die 108 when no mold compound 110 is present. In FIG. 1, the MTIM retainer 166 contacts the top surface 112 of the IC die 108 and the bottom surface 156 of the roof 140 of the lid 106. The MTIM retainer 166 also contacts the MTIM 150.

The chip package 100 illustrated in FIG. 1 may be also be interfaced with a thermal regulating device (not shown). The thermal regulating device is disposed against the top surface of the roof 140 of the lid 106 and may include an active and/or passive heat transfer elements, such as fins, forced liquid channels, forced gas channels, vapor cavities, phase change materials, and/or heat pipes, among other heat transfer enhancing elements. The thermal regulating device is utilized to remove heat through the lid 106 and the MTIM 150 from the IC die complex 102, thus enhancing the reliability and performance of the IC dies 108, and consequently, improving the reliability and performance of the chip package 100.

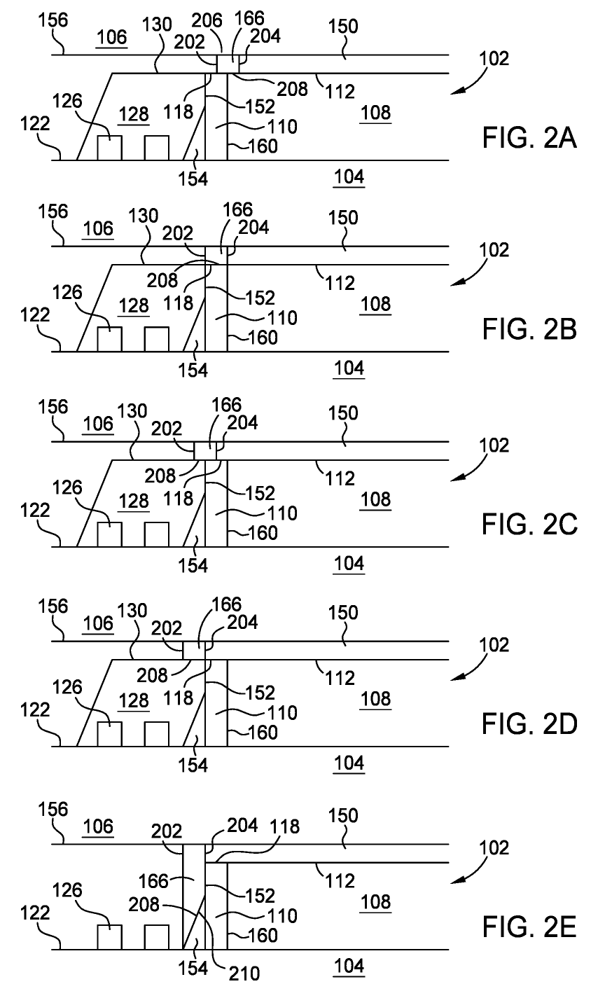

FIG. 2A through FIG. 2E are partial sectional views of the chip package 100 illustrating different locations of the MTIM retainer 166. In the example depicted in FIG. 2A, the MTIM retainer 166 is shown disposed partially on the IC die 108 and at least partially on the mold compound 110. The MTIM retainer 166 depicted in FIG. 2A includes a first sidewall 202, a second sidewall 204, a third sidewall 206 and a fourth sidewall 208. The first sidewall 202 faces away from the fourth sidewall 208, and the second sidewall 204 faces away from the third sidewall 206. The second sidewall 204 is in contact with the first MTIM 150. Optionally, the second sidewall 204 may be slightly spaced from the first MTIM 150. The first sidewall 202 is in contact with the bottom surface 156 of the roof 140 of the lid 106. The fourth sidewall 208 is in contact with the top surface 112 of the IC die 108 and the margin 118 of the mold compound. 110. The MTIM retainer 166 may start before the mold compound 110 (as shown in FIG. 2A) and can extend all the up to the outermost edge (i.e., edge away from IC die 108) of the spacer 128, and include all the variations of starting point and ending point locations of the retainer 166 in between the mold compound 110 and the outermost edge of the spacer 128.

In the example depicted in FIG. 2B, the MTIM retainer 166 is shown disposed on the mold compound 110. The fourth sidewall 208 of the MTIM retainer 166 is in contact with the top surface 116 of the margin 118 of the mold compound. 110. The first MTIM 150 may be in contact with the second sidewall 204 and extend at least partially over the margin 118 of the mold compound 110.

In the example depicted in FIG. 2C, the MTIM retainer 166 is shown disposed on the top surface 116 of the mold compound 110 and at least partially on the top surface 130 of the spacer 128. The first MTIM 150 may be in contact with the second sidewall 204 and the margin 118 of the mold compound 110.

In the example depicted in FIG. 2D, the MTIM retainer 166 is shown disposed on the top surface 130 of the spacer 128. The MTIM retainer 166 is clear of the margin 118 of the mold compound 110. The first MTIM 150 may be in contact with the second sidewall 204 and the top surface 116 of the margin 118 of the mold compound 110. The first MTIM 150 may also be in contact with top surface 130 of the spacer 128.

In the example depicted in FIG. 2E, the MTIM retainer 166 is shown disposed on a top surface 210 of the underfill 154. In the exampled depicted in FIG. 2E, the MTIM retainer 166 is clear of the margin 118 of the mold compound 110. Optionally, the MTIM retainer 166 may be contact with both the top surface 116 of the margin 118 of the mold compound 110 and the top surface 210 of the underfill 154. The first MTIM 150 may be in contact with the second sidewall 204 of the MTIM retainer 166 or be spaced therefrom, with the first MTIM 150.

In other examples, the MTIM retainer 166 may extend over the underfill 154 and contact the top surface 122 of the substrate 104. In yet other examples where underfill 154 is not present on the outer surface of the margin 118 that defines the outer sidewall 152 of the chip complex 102, the MTIM retainer 166 may extend over the outer surface of the margin 118 of the mold compound 110 and contact the top surface 122 of the substrate 104.

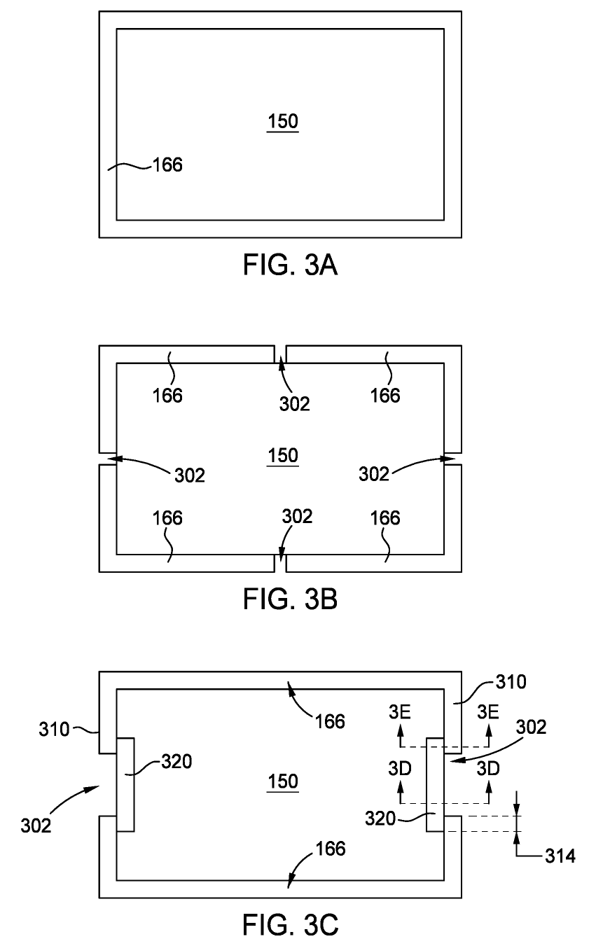

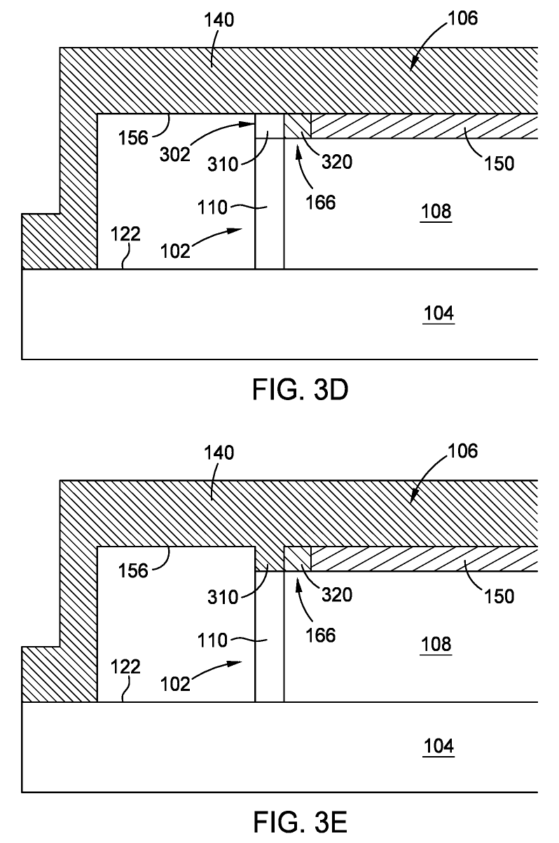

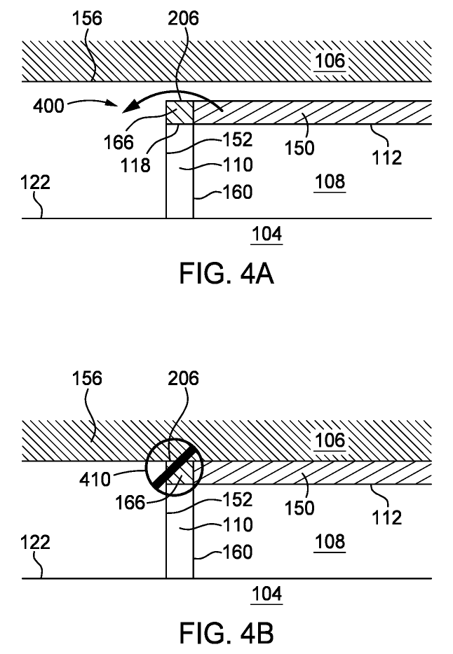

FIG. 3A is a schematic top view of the MTIM retainer 166 surrounding the MTIM 150. In the example depicted in FIG. 3A, the MTIM retainer 166 contiguously surrounds the MTIM 150. Optionally, the MTIM retainer 166 may include one or more vents 302 formed through the MTIM retainer 166 as illustrated in FIG. 3B. The vents 302 allows the MTIM 150 to outgas during initial fabrication stages of the chip package 100 through the MTIM retainer 166, thus reducing the probability of voids forming in the MTIM 150 or at the interface between the MTIM 150 and the bottom surface 156 of the lid 106 and/or the top surface 112 of the IC die 108.

The vents 202 may have an alternative configuration, as shown in FIG. 3C. In the example depicted in FIG. 3A, the MTIM retainer 166 includes a barrier wall 310 and an MTIM portion 320. The barrier wall 310 generally surrounds the first MTIM 150 and includes an opening that forms a portion of the vent 302. The barrier wall 310 may be a solid structure, an adhesive, or other material having a service temperature greater than 240 degrees. The MTIM portion 320 is disposed across the opening in the barrier wall 310 that forms the vent 202. The MTIM portion 320 and the barrier wall 310 are overlapped by a distance 314. The material of the MTIM portion 320 is generally selected to allow the first MTIM 150 to outgas through and/or around the MTIM portion 320 when the first MTIM 150 is heated above about 240 degrees Celsius during the initial stages of the chip package fabrication process.

In one example, the MTIM portion 320 is a second metal thermal interface material (relative to the first MTIM 150) that has a melting temperature greater than a melting temperature of the MTIM 150. For example, the melting point of the MTIM portion 320 comprised of the second MTIM is greater than a ball grid array (BGA) reflow temperature. In another example, the melting point of the MTIM portion 320 is greater than about 240 degrees Celsius.

In still another example, the MTIM portion 320 is comprised of a permeable metal material. The permeable metal material allows the MTIM 150 to outgas through the MTIM portion 320 during fabrication of the chip package 100. In this example, the permeable metal material is one or more of a metal foam, a metal mesh, a metal wool, and the like. In a specific example, the MTIM portion 320 is fabricated from copper, such as copper foam, copper mesh, copper wool and the like.

FIGS. 3D and 3E are partial sectional views of the chip package 100, taken along section lines 3D- - 3D and 3E - - 3E of FIG. 3C, illustrating the relative locations of the MTIM portion 320 and the barrier wall 310. The barrier wall 310 is generally outward of the MTIM portion 320, and spans across the opening defining the vent 302. The barrier wall 310 may alternatively be disposed in the opening in the MTIM portion 320 opening defining the vent 302. The barrier wall 310 may be part of the lid 106 or the mold compound 110; be a separate structure disposed on the top surface 112 of the IC die 108, the top surface (margin 118) of the mold compound 110, the underfill 154, or the top surface 130 of the spacer 128; or be a standalone structure disposed on a top surface 122 of the substrate 104. In the example depicted in FIG. 3D, the barrier wall 310 is a solid structure disposed on the mold compound 110, or alternatively, the bottom surface 156 of the lid 106. In the example depicted in FIG. 3E, the barrier wall 310 is a lip projecting from the bottom surface 156 of the lid 106.

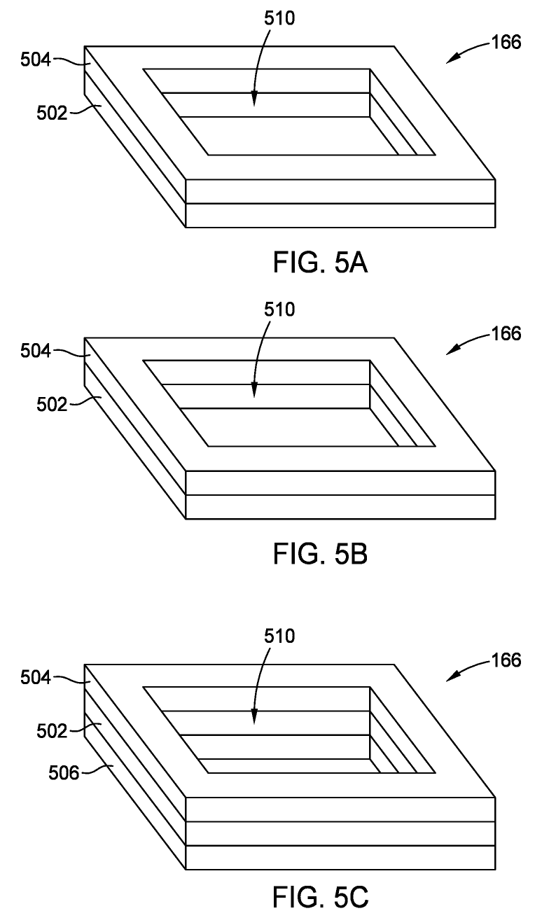

FIG. 4A and FIG. 4B depict the flow of gas outgassed from MTIM 150 to outgas across the MTIM retainer 166 during initial fabrication stages of the chip package 100 when the MTIM retainer 166 is fabricated from a second MTIM having a melting temperature higher than that of the MTIM 150. After the lid 106 has been placed over the MTIM 150 and MTIM retainer 166, and prior to heating the chip package above the melting point of the second MTIM material comprising the MTIM retainer 166, gas outgassed from the MTIM 150 can flow across the MTIM retainer 166 as shown by arrow 400 as shown in FIG. 4A. Note that in FIG. 4A, the lid 106 is shown spaced from the MTIM 150 and the MTIM retainer 166 for purposes of illustration so that the depiction of the gas movement shown by the arrow 400 may be more readily shown. In actually, the MTIM 150 and the MTIM retainer 166 touch the bottom surface 156 of the roof 140 of the lid 106, but the interface between the MTIM retainer 166 and the bottom surface 156 of the roof 140 (and/or the top surface 112 of the IC die 108) is not initially gas tight, thus allowing the movement of gas across the MTIM retainer 166.

After the MTIM retainer 166 has been heated above its melting temperature, the MTIM retainer 166 wets and creates a gas tight seal with the bottom surface 156 of the roof 140 and the top surface 112 of the IC die 108, thereby not permitting the movement of gas outgassed from the MTIM 150 across the MTIM retainer 166, as illustrated by the Ø sign in FIG. 4B.

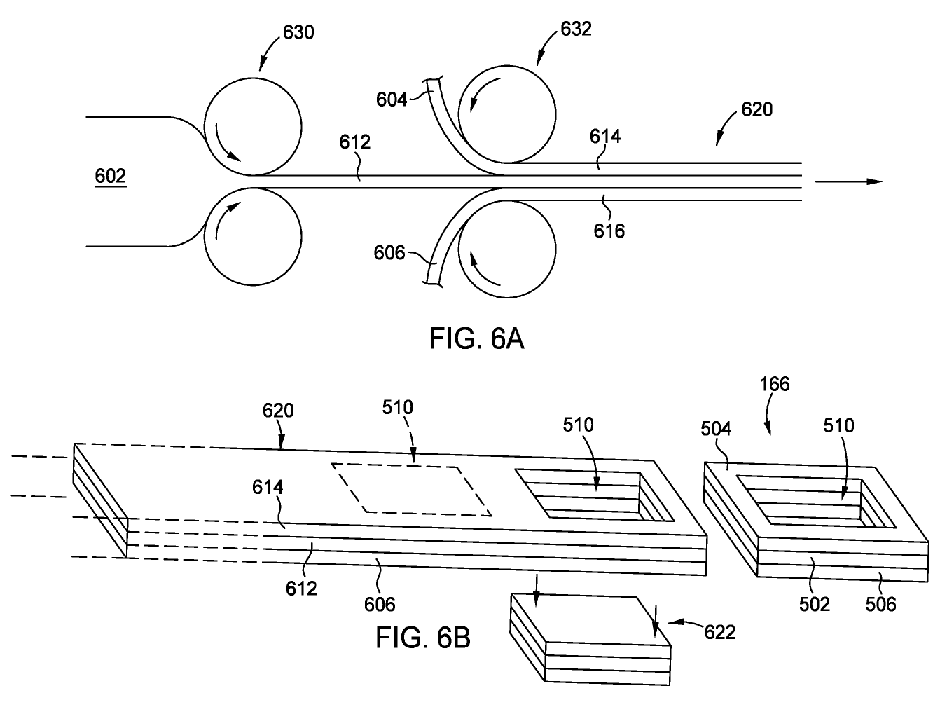

FIGS. 5A-5C depict various alternative examples of the MTIM retainer 166. Although not shown in the examples depicted in FIGS. 5A-5C, the MTIM retainer 166 may also include vents 302 as described above with reference to FIGS. 3B-3C.

Referring first to the isometric view of the MTIM retainer 166 depicted in FIG. 5A, the MTIM retainer 166 includes a first layer 502 stacked with a second layer 502. The stacked first and second layers 502, 504 have a frame shape defining a central opening 510. The central opening 510 is configured to confine the first MTIM 150 when the chip package 100 is assembled. In one example, the central opening 510 may be formed by die punching a sheet comprised of the laminated first and second layers 502, 504. The first MTIM 150 is not shown in FIG. 5A. The first MTIM 150 may be disposed in the opening 510 prior to being disposed on the IC die 108 of the chip complex 102 of the chip package 100. Alternatively, the MTIM retainer 166 may be disposed around the first MTIM 150 after the first MTIM 150 has been disposed on the IC die 108. In still another alternative example, the first MTIM 150 may be disposed on the IC die 108 after the MTIM retainer 166 has been disposed around the first IC die 108.

In the example depicted in FIG. 5A, the first layer 502 is a metal core. The first layer 502 may be a flat sheet of metal. The metal core comprising the first layer 502 may be fabricated from stainless steel, aluminum, copper, nickel coated copper, or other suitable metal or other highly thermally conductive material. The metal core may optionally be a permeable metal material such as a metal foam, a metal mesh, a metal wool, and the like.

The second layer 504 is configured to provide a seal with the bottom surface 156 of the lid 106 upon installation of the lid 106 with the other components of the chip package 100. In one example, the second layer 504 is an adhesive material. In another example, the second layer 504 is a second metal thermal interface material (relative to the first MTIM 150) that has a melting temperature greater than a melting temperature of the MTIM 150. For example, the melting point of the second layer 504 comprised of the second MTIM is greater than a ball grid array (BGA) reflow temperature. In another example, the melting point of the second layer 504 is greater than about 240 degrees Celsius.

FIG. 5B depicts an isometric view of another example of an MTIM retainer 166. The MTIM retainer 166 depicted in FIG. 5B is similar to the MTIM retainer 166 depicted in FIG. 5A, except that instead of the first layer 502 being laminated with the second layer 504, the first layer 502 is laminated with a third layer 506 while the second layer 504 is omitted.

The third layer 506 is configured to provide a seal with the top surface 112 of the IC die 108 (and/or mold compound 110 and/or spacer 128). In one example, the third layer 506 is an adhesive material. In another example, the third layer 506 is a second metal thermal interface material (relative to the first MTIM 150) that has a melting temperature greater than a melting temperature of the MTIM 150. For example, the melting point of the third layer 506 comprised of the second MTIM is greater than a ball grid array (BGA) reflow temperature. In another example, the melting point of the third layer 506 is greater than about 240 degrees Celsius.

FIG. 5C depicts an isometric view of another example of an MTIM retainer 166. The MTIM retainer 166 depicted in FIG. 5C is similar to the MTIM retainer 166 depicted in FIG. 5A, except with the addition of a third layer 506 that is stacked with the first and second layers 502, 504. In the MTIM retainer 166, the first layer 502 is sandwiched by the second and third layers 504, 506.

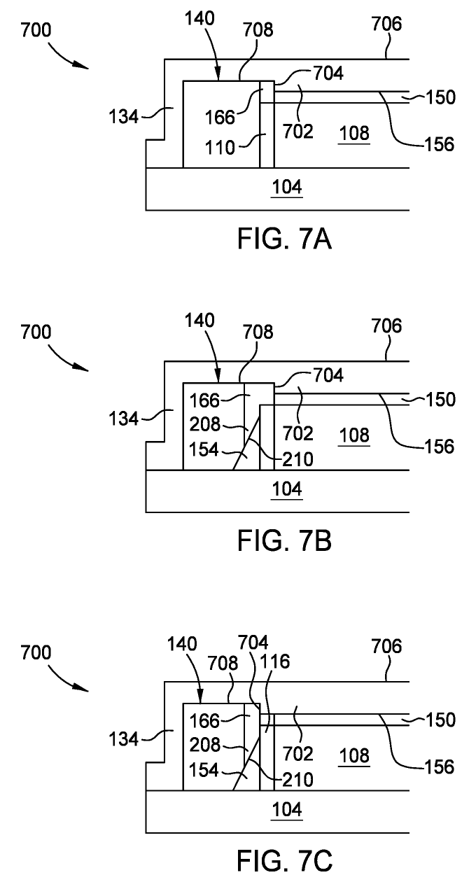

FIGS. 6A and 6B are schematic diagrams of one example of how the MTIM retainer 166 depicted in FIG. 5C and having the laminated layers 502, 504, 506 may be fabricated. As illustrated in FIG. 6A, bulk core material 602 is fed between rollers 630 to produce a core web 612. The bulk core material 602 is made of the same materials as the first layer 502 of the MTIM retainer 166, as the bulk core material 602 is used to fabricate the MTIM retainer 166. Laminating materials 604, 604 are laminated with core web 612 using rollers 632 to form a MTIM retainer web 620. The laminating materials 604, 604 later form the second and third layers 504, 506, and thus are the same materials as described above with respect to the second and third layers 504, 506.

As depicted in FIG. 6B, the MTIM retainer web 620 is punched to remove a slug 622, thus forming an opening 510 through the web 620. The MTIM retainer web 620 is then sliced to form individual MTIM retainers 166, each MTIM retainer 166 having at least one or more openings 510.

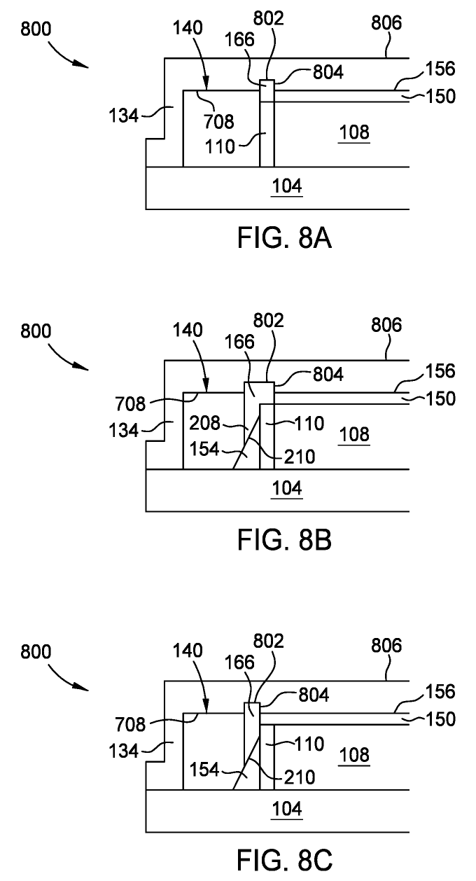

FIG. 7A-7C are partial sectional views of another example of a chip package 700 having a lid 706 that includes a pad 702 configured enhance the functionality of the MTIM retainer 166. The chip package 700 is substantially the same as any of the chip packages described above, except in that the roof 140 of the lid 706 includes a pad 702 that extends downward from an outer portion 708 of the roof 140. The outer portion 708 of the roof 140 is adjacent the ring base 134. The pad 702 defines the bottom surface 156 of the roof 140 which is spaced above the IC dies 108 of the chip complex 102.

The pad 702 includes a sidewall 704 that extends between the outer portion 708 and the bottom surface 156 of the roof 140. The MTIM retainer 166 extends above the MTIM 150 and abuttingly along the sidewall 704. Thus, the sidewall 704 functions to discourage the MTIM retainer 166 from moving above the MTIM 150 while heated.

In FIG. 7A, the MTIM retainer 166 is disposed over the mold compound 110, and contacts the sidewall 704 of the pad 702 and the outer portion 708 of the roof 140. In FIG. 7B, the MTIM retainer 166 is disposed over the mold compound 110 and in contact with the underfill 154, and also contacts the sidewall 704 of the pad 702 and the outer portion 708 of the roof 140. In FIG. 7C, the MTIM 150 is disposed over the top of the mold compound 110, while the MTIM retainer 166 is in contact with the underfill 154, the side of the mold compound 110, the sidewall 704 of the pad 702 and the outer portion 708 of the roof 140.

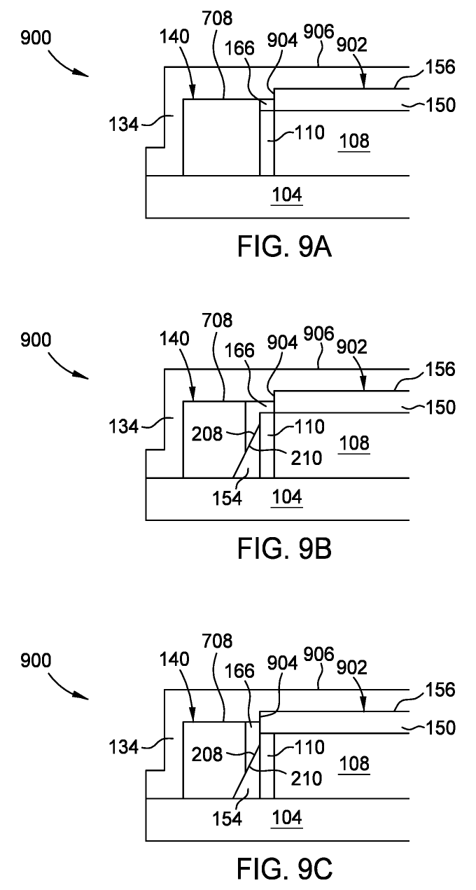

FIG. 8A-8C are partial sectional views of a chip package 800 having a lid 806 that includes a gutter 802 configured enhance the functionality of the MTIM retainer 166. The chip package 800 is substantially the same as any of the chip packages described above, except in that the roof 140 of the lid 806 includes a gutter 802 that extends downward from an outer portion 708 of the roof 140. The outer portion 708 of the roof 140 is adjacent the ring base 134. The gutter 802 is formed in the roof 140 between the outer portion 708 and the bottom surface 156 of the roof 140 which is spaced above the IC dies 108 of the chip complex 102. In one example, the gutter 802 is a slot formed into the roof 140 of the lid 806.

The gutter 802 includes a sidewall 804 that terminates at the bottom surface 156 of the roof 140. The MTIM retainer 166 extends into the gutter 802 above the MTIM 150 and abuttingly along the sidewall 804. Thus, the sidewall 804 and gutter 802 functions to discourage the MTIM retainer 166 from moving above the MTIM 150 while heated.

In FIG. 8A, the MTIM retainer 166 is disposed over the mold compound 110, and extends into the gutter 802. In FIG. 8B, the MTIM retainer 166 is disposed in the gutter 802 and over the mold compound 110. The MTIM retainer 166 is in contact with the top and sides of the mold compound 110, and additionally, the underfill 154. In FIG. 8C, the MTIM 150 is disposed over the top of the mold compound 110, while the MTIM retainer 166 is disposed in the gutter 802 and in contact with the underfill 154, the side of the mold compound 110, the sidewall 704 of the pad 702 and the outer portion 708 of the roof 140.

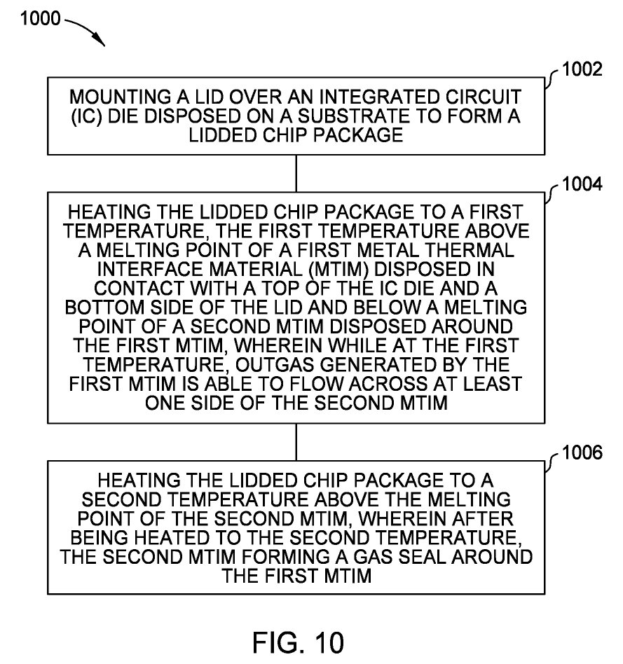

FIG. 9A-9C are partial sectional views of a chip package 800 having a lid 906 that includes a recess 902 configured enhance the functionality of the MTIM retainer 166. The chip package 700 is substantially the same as any of the chip packages described above, except in that the roof 140 of the lid 906 includes a recess 902 that extends downward from an outer portion 708 of the roof 140. The recess 902 defines the bottom surface 156 of the roof 140 which is spaced above the IC dies 108 of the chip complex 102.

The recess 902 includes a sidewall 904 that extends between the outer portion 708 and the bottom surface 156 of the roof 140. The MTIM 150 extends into the recess 902 and abuttingly along the sidewall 704. The MTIM retainer 166 is disposed in contact with the outer portion 708 outside of the recess 902, and thus below the top surface of the MTIM 150. Thus, the recess 902 functions to discourage the MTIM retainer 166 from moving above the MTIM 150 while heated.

In FIG. 9A, the MTIM retainer 166 is disposed over the mold compound 110 outward of the recess 902, and contacts the outer portion 708 of the roof 140 and a portion of the side but is spaced from the top of the MTIM 150. In FIG. 9B, the MTIM retainer 166 is disposed over the mold compound 110 and in contact with the underfill 154. In FIG. 9C, the recess 902 extends over the top of the mold compound 110 such that the MTIM 150 is in contact with both the bottom surface 156 and sidewall 904 of the recess. The MTIM retainer 166 is disposed outward of the recess 902, and is in contact with the underfill 154, the side of the mold compound 110, and the outer portion 708 of the roof 140.

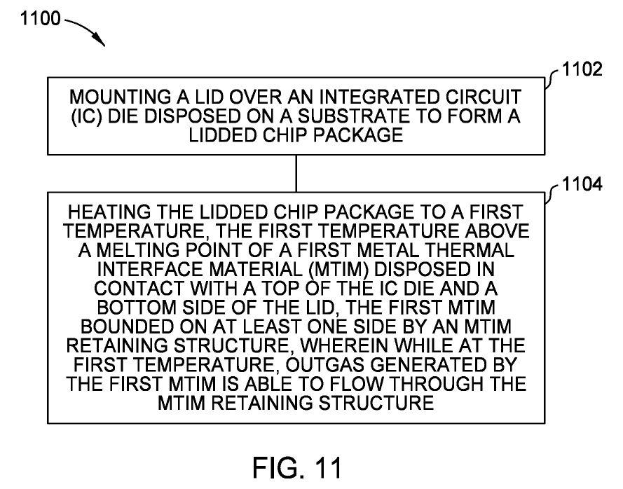

FIG. 10 is a flow diagram of a method 1000 for forming a lidded chip package, such as the chip package 100 described above, or other lidded chip package that includes retained metal thermal interface material. The method 1000 for fabricating a chip package begins at operation 1002 by mounting a lid over an integrated circuit (IC) die disposed on a substrate to form a lidded chip package. The IC die may be a singular IC die, or an IC die that is part of a chip complex.

At operation 1004, the lidded chip package is heated to a first temperature. The first temperature is above a melting point of a first metal thermal interface material that is disposed in contact with a top of the IC die and a bottom side of the lid. The first temperature is also below a melting point of a second metal thermal interface material that is disposed around the first metal thermal interface material. While at the first temperature, first metal thermal interface material outgasses, and the generated gases are able to flow across at least one side of the second metal thermal interface material. By allowing the outgassed gas to flow away from the first metal thermal interface material, the probability of voids is advantageously reduced, then improving the efficiency and effectiveness of heat transfer from the IC die to the lid. In one example, the first temperature is greater than about 160 degrees Celsius and less than about 240 degrees Celsius.

At operation 1006, the lidded chip package is heated to a second temperature that is above the melting point of the second metal thermal interface material. After being heated to the second temperature, the second metal thermal interface material essentially forms a gas seal around the first metal thermal interface material. The gas seal provided by the post-heated second metal thermal interface material advantageously reduces the potential of the first metal thermal interface material from pumping out from between the lid and IC die during later occurring solder reflow processes. In one example, the second temperature is greater than about 240 degrees Celsius, such as greater than about 250 degrees Celsius.

The lidded chip package is generally allowed to cool below 160 degrees Celsius prior to reheating for the solder ball (BGA) reflow. In one example, the BGA reflow temperature is between the first and second temperatures.

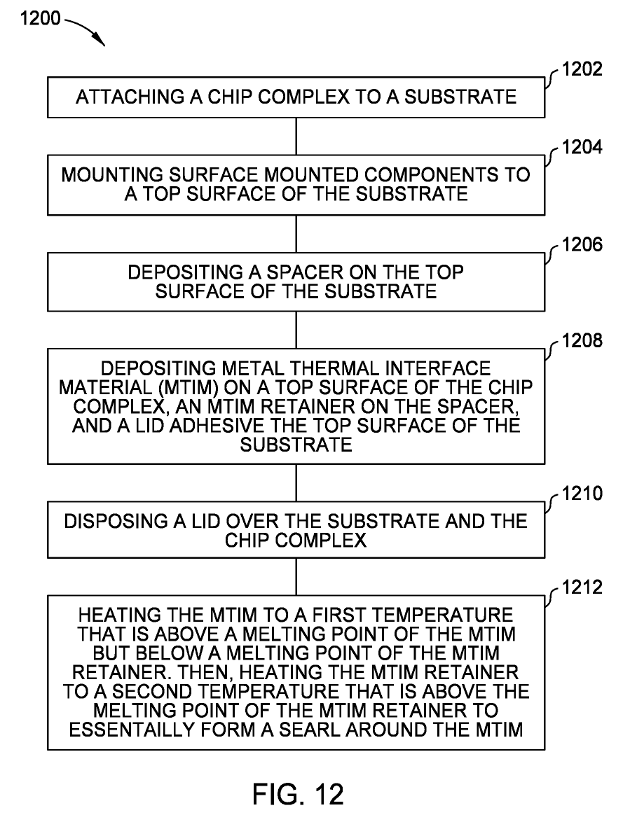

FIG. 11 is a flow diagram of another method 1100 for forming a lidded chip package, such as the chip package 100 described above, or other lidded chip package that includes retained metal thermal interface material. The method 1100 for fabricating a chip package begins at operation 1102 by mounting a lid over an integrated circuit (IC) die disposed on a substrate to form a lidded chip package. The IC die may be a singular IC die, or an IC die that is part of a chip complex.

At operation 1104, the lidded chip package is heated to a first temperature. The first temperature is above a melting point of a first metal thermal interface material that is disposed in contact with a top of the IC die and a bottom side of the lid. The first temperature is above a melting point of a first metal thermal interface material that is disposed in contact with a top of the IC die and a bottom side of the lid. The second metal thermal interface material bounded on at least one side by a thermal interface retaining structure. While at the first temperature, outgas generated by the first metal thermal interface material is able to flow through the thermal interface retaining structure.

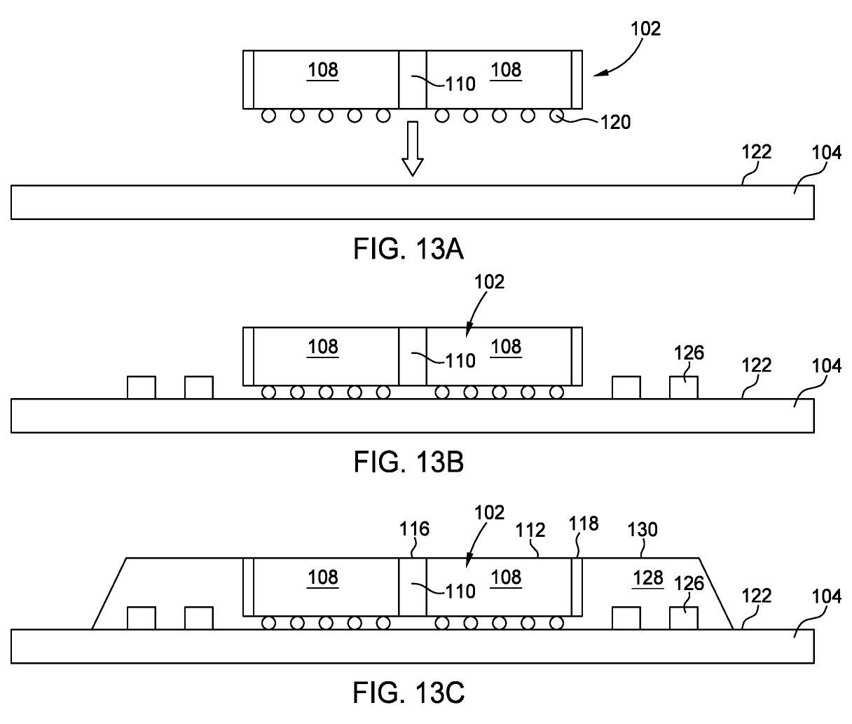

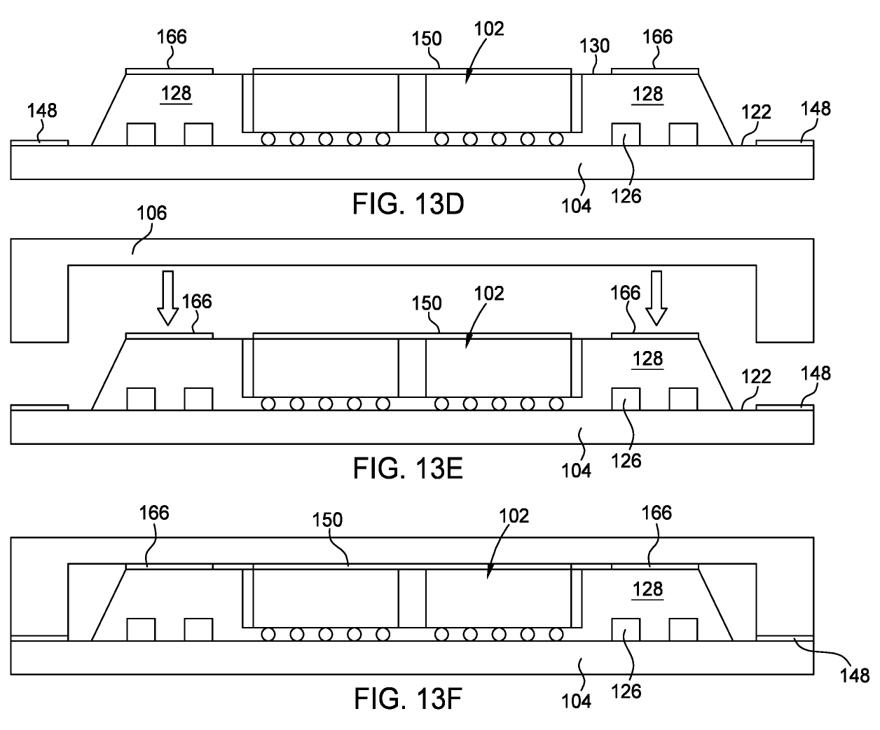

FIG. 12 is a flow diagram of another example of a method 1200 for forming a lidded chip package, such as the chip package 100 described above, or other lidded chip package that includes retained metal thermal interface material. FIGS. 13A-13F are schematic side views of a chip package in different stages of fabrication, such as when fabricated in accordance to the method 1200.

The method 1200 begins at operation 1202 by attaching a chip complex 202 to a substrate 104, as illustrated in FIG. 13A. The chip complex 202 may be attached to the substrate 104 via solder interconnects 120 or by another suitable manner.

At operation 1204, surface mounted components 126 are mounted to the substrate 104, as illustrated in FIG. 13B. Operation 1204 may be performed before or after operation 1202.

At operation 1206, a spacer 128 is deposited on the top surface 122 of the substrate 104, as illustrated in FIG. 13C. The spacer 128 may be deposited by any suitable technique, such as molding or dispensing. The spacer 128 encapsulates some or all of the surface mounted components 126 disposed on the top surface 122 of the substrate 104.

Operation 1206 may also include planarizing the top surfaces of the chip complex 102, mold compound 110 and spacer 128. The top surfaces may be planarized by milling, grinding, etching or other suitable technique.

At operation 1208, MTIM 150, an MTIM retainer 166 and a lid adhesive 148 are deposited, as shown in FIG. 13D. The MTIM 150 is placed on the top surface of the chip complex 102. The MTIM 150 may be a preformed sheet that is robotically disposed on the chip complex 102. The MTIM 150 may alternatively be dispensed on the chip complex 102. The MTIM retainer 166 is disposed on the spacer 128. The MTIM retainer 166 may be a preformed sheet that is robotically disposed on the spacer 128. The MTIM retainer 166 may alternatively be dispensed on the spacer 128. The lid adhesive 148 is disposed on the top surface 122 of the substrate 104. The lid adhesive 148 may be a preformed sheet that is robotically disposed on the top surface 122 of the substrate 104. The lid adhesive 148 may alternatively be dispensed on the top surface 122 of the substrate 104.

At operation 1210, the lid 106 is disposed over the substrate 104 and chip complex 102, as shown in FIGS. 13E and 13F. The lid 106 is attached to the substrate 104 via the lid adhesive 148. The lid adhesive 148 may be heated to cure the adhesive 148. At operation 1212, the MTIM 150 is then captured by the MTIM retainer 166 utilizing the techniques described in the methods 1000, 1100 detailed above, or other suitable technique. In one example, the MTIM 150 is heated to a first temperature that is above a melting point of the MTIM 150 but below a melting point of the MTIM retainer 166. Then, the MTIM retainer 166 is heated to a second temperature that is above the melting point of the MTIM retainer 166 to essentially form seal (i.e., a flow barrier) around the MTIM 150.

In addition to the examples described above, the disclosed technology may also be expressed in the following non-limiting examples.

Example 1. A chip package including: a substrate; an integrated circuit (IC) die having a bottom surface facing a top surface of the substrate; a first metal thermal interface material (MTIM) disposed on a top surface of the IC die; a lid disposed over the IC die, the lid having a bottom side contacting the first MTIM; and a retaining structure disposed outwardly of the first MTIM, the retaining structure capturing the first MTIM on the top surface of the IC die.

Example 2. The chip package of Example 1, wherein the retaining structure is a second MTIM having a melting point higher than a melting point of the first MTIM.

Example 3. The chip package of Example 2, wherein the melting point of the second MTIM is greater than a ball grid array (BGA) reflow temperature.

Example 4. The chip package of Example 2, wherein the melting point of the second MTIM is greater than about 240 degrees Celsius.

Example 5. The chip package of Example 2, wherein the second MTIM is disposed at least partially on the top surface of the IC die.

Example 6. The chip package of Example 2 further including: a pre-substrate mounting mold material disposed on at least one sidewall of the IC die, the pre-substrate mounting mold material having a top surface substantially coplanar with the top surface of the IC die, wherein the second MTIM is disposed at least partially on the top surface of the pre-substrate mounting mold material.

Example 7. The chip package of Example 2 further including: a post-substrate mounting mold material disposed on a top surface of the substrate adjacent to at least one sidewall of the IC die, the post-substrate mounting mold material having a top surface substantially coplanar with the top surface of the IC die, wherein the second MTIM is disposed at least partially on the top surface of the first the post-substrate mounting mold material.

Example 8. The chip package of Example 2, wherein the second MTIM circumscribes the first MTIM.

Example 9. The chip package of Example 8, wherein the second MTIM further includes one or more vent passages operable to allow the first MTIM to outgas through the second MTIM.

Example 10. The chip package of Example 2, wherein the first MTIM is gallium, gallium-based alloy, indium or indium alloy.

Example 11. The chip package of Example 11, wherein the second MTIM is a tin-based material.

Example 12. The chip package of Example 2, wherein the retaining structure includes: a thermally conductive ring having a top side and a bottom side; and a second MTIM disposed at least on one of the bottom side or the top side of the thermally conductive ring.

Example 13. The chip package of Example 12, wherein the thermally conductive ring is a flat copper ring.

Example 14. The chip package of Example 2, wherein the retaining structure includes: a thermally conductive ring having a top side and a bottom side; a second MTIM disposed on the top side of the thermally conductive ring; and a third MTIM disposed on the bottom side of the thermally conductive ring, the third MTIM having a melting point higher than a melting point of the first MTIM.

Example 15. The chip package of Example 1, wherein the retaining structure includes: a lip disposed outward of and extending around the first MTIM, the lip having at least a first gap; and a second MTIM between the first MTIM and the first gap, the second MTIM having a melting point higher than a melting point of the first MTIM or including a permeable metal material.

Example 16. The chip package of Example 15, wherein the second MTIM is a permeable metal material, and the permeable metal material is a metal foam, a metal mesh, a metal wool, and the like.

Example 17. The chip package of Example 1, wherein the retaining structure is an adhesive.

Example 18. The chip package of Example 17, wherein the adhesive is disposed at least partially on the top surface of the IC die.

Example 19. The chip package of Example 17 further including: a pre-substrate mounting mold material disposed on at least one sidewall of the IC die, the pre-substrate mounting mold material having a top surface substantially coplanar with the top surface of the IC die, wherein the adhesive is disposed at least partially on the top surface of the pre-substrate mounting mold material.

Example 20. The chip package of Example 17, wherein the IC die is part of a mold complex; and wherein the chip package further includes: an underfill fillet disposed on the top surface of the substrate and in contact with a sidewall of the IC die, the underfill fillet having a top surface having the adhesive disposed thereon, the adhesive extending above the top surface of the IC die.

Example 21. The chip package of Example 17, wherein the adhesive circumscribes the first MTIM.

Example 22. The chip package of Example 21, wherein the adhesive further includes one or more vent passages operable to allow the first MTIM to outgas through the adhesive.

Example 23. The chip package of Example 21, wherein the first MTIM is gallium, gallium-based alloy, indium or indium alloy.

Example 24. The chip package of Example 17, wherein the adhesive is (add material list for adhesive) based.

Example 25. The chip package of Example 17, wherein the bottom side of the lid contacts the adhesive.

Example 26. The chip package of Example 25, wherein the bottom side of lid further includes: a bottom surface and a recess formed in the bottom surface, wherein the bottom surface is in contact with the adhesive and the first MTIM extends beyond the bottom surface into the recess.

Example 27. The chip package of Example 25, wherein the bottom side of lid further includes: a bottom surface and a trench formed in the bottom surface, wherein the bottom surface is in contact with the first MTIM and the adhesive extends beyond the bottom surface into the trench.

Example 28. The chip package of Example 25, wherein the bottom side of lid further includes: a bottom surface and a pad extending from the bottom surface, wherein the pad is in contact with the first MTIM and the adhesive extends beyond the pad and is in contact with bottom surface of the bottom side of the lid.

Example 29. The chip package of Example 17 further including: a post-substrate mounting mold material disposed on a top surface of the substrate adjacent to at least one sidewall of the IC die, the post-substrate mounting mold material having a top surface, the adhesive disposed on the top surface of the first the post-substrate mounting mold material.

Example 30. The chip package of Example 29, wherein the bottom side of the lid contacts the adhesive.

Example 31. The chip package of Example 30, wherein the lid further includes: a sidewall extending from the bottom side of the lid, the sidewall secured to the substrate.

Example 32. The chip package of Example 30, wherein the bottom side of the lid further includes: a ring surrounding an inner portion of the bottom side, the adhesive in contact with the ring and the first MTIM extending beyond the ring and in contact with the inner portion of the bottom side of the lid.

Example 33. The chip package of Example 29, wherein the post-substrate mounting mold material encapsulates surface mounted components disposed on the substrate.

Example 34. The chip package of Example 29, wherein the adhesive further includes one or more vent passages operable to allow the first MTIM to outgas through the adhesive.

Example 35. The chip package of Example 29, wherein the first MTIM is gallium, gallium-based alloy, indium or indium alloy.

Example 36. The chip package of Example 29, wherein the adhesive is (add material list for adhesive) based.

Example 37. The chip package of Example 1, wherein the retaining structure is a foamed material.

Example 38. The chip package of Example 1, wherein the retaining structure is a foamed metal.

Example 39. The chip package of Example 38, wherein the foamed metal includes one or more vent passages operable to allow the first MTIM to outgas through the foamed metal.

Example 40. The chip package of Example 38, wherein the foamed metal is disposed at least partially on the top surface of the IC die.

Example 41. The chip package of Example 38 further including: a pre-substrate mounting mold material disposed on at least one sidewall of the IC die, the pre-substrate mounting mold material having a top surface substantially coplanar with the top surface of the IC die, wherein the foamed metal is disposed at least partially on the top surface of the pre-substrate mounting mold material.

Example 42. The chip package of Example 38 further including: a post-substrate mounting mold material disposed on a top surface of the substrate adjacent to at least one sidewall of the IC die, the post-substrate mounting mold material having a top surface, wherein the foamed metal is disposed at least partially on the top surface of the first the post-substrate mounting mold material.

Example 43. The chip package of Example 38, wherein the foamed metal circumscribes the first MTIM.

Example 44. The chip package of Example 38, wherein the first MTIM is gallium, gallium-based alloy, indium or indium alloy.

Example 45. The chip package of Example 38, wherein the foamed metal includes copper.

Example 46. The chip package of Example 38 further including: a lid disposed over the IC die, the lid having a bottom side contacting the foamed metal and the first MTIM.

Example 47. A method for fabricating a chip package including: mounting a lid over an integrated circuit (IC) die disposed on a substrate to form a lidded chip package; heating the lidded chip package to a first temperature, the first temperature above a melting point of a first metal thermal interface material disposed in contact with a top of the IC die and a bottom side of the lid and below a melting point of a second metal thermal interface material disposed around the first metal thermal interface material, wherein while at the first temperature, outgas generated by the first metal thermal interface material is able to flow across at least one side of the second metal thermal interface material; heating the lidded chip package to a second temperature above the melting point of the second metal thermal interface material, wherein after being heated to the second temperature, the second metal thermal interface material forming a gas seal around the first metal thermal interface material.

Example 48. A method for fabricating a chip package including: mounting a lid over an integrated circuit (IC) die disposed on a substrate to form a lidded chip package; heating the lidded chip package to a first temperature, the first temperature above a melting point of a first metal thermal interface material disposed in contact with a top of the IC die and a bottom side of the lid, the second metal thermal interface material bounded on at least one side by a thermal interface retaining structure, wherein while at the first temperature, outgas generated by the first metal thermal interface material is able to flow through the thermal interface retaining structure.

Thus, chip packages that provide effective utilization of MTIM resulting in enhanced heat transfer between IC dies and the lid of chip packages, along with techniques for fabricating the same, have been described above. The chip packages described above leverage thermal interface retaining structures to keep the MTIM in a desired location, thus improving performance and reliability. The novel picture frame shaped thermal interface retaining structure disposed around an edge of the IC die significantly prevent pump-out of the MTIM upon securing a lid to the chip package and/or during ball grid array (BGA) during fabrication. In some examples, the material comprising the thermal interface retaining structure is selected to allow degassing of the MTIM, while still retaining the MTIM its desired location over the IC die. The innovative thermal interface retaining structures, material selection, and fabrication process enables lidded chip packages to have improved thermal performance, which is especially important for high performance compute products where the power consumption is approaching and exceeding 1000 Watts. Thus, the thermal interface retaining structures described herein promote good heat transfer, along with robust and reliable computing performance.

What is claimed is:

1. A chip package comprising:
a substrate;
an integrated circuit (IC) die having a bottom surface facing a top surface of the substrate;
a first metal thermal interface material (MTIM) disposed on a top surface of the IC die;
a lid disposed over the IC die, the lid having a bottom side contacting the first MTIM; and
a retaining structure disposed outwardly of the first MTIM, the retaining structure capturing the first MTIM on the top surface of the IC die.

2. The chip package of claim 1, wherein the retaining structure is a second MTIM having a melting point higher than a melting point of the first MTIM.

3. The chip package of claim 2, wherein the melting point of the second MTIM is greater than a ball grid array (BGA) reflow temperature.

4. The chip package of claim 2, wherein the melting point of the second MTIM is greater than about 240 degrees Celsius.

5. The chip package of claim 2, wherein the second MTIM is disposed at least partially on the top surface of the IC die.

6. The chip package of claim 2 further comprising:
a pre-substrate mounting mold material disposed on at least one sidewall of the IC die, the pre-substrate mounting mold material having a top surface substantially coplanar with the top surface of the IC die, wherein the second MTIM is disposed at least partially on the top surface of the pre-substrate mounting mold material.

7. The chip package of claim 2 further comprising:
a post-substrate mounting mold material disposed on a top surface of the substrate adjacent to at least one sidewall of the IC die, the post-substrate mounting mold material having a top surface substantially coplanar with the top surface of the IC die, wherein the second MTIM is disposed at least partially on the top surface of the first post-substrate mounting mold material.

8. The chip package of claim 2, wherein the second MTIM circumscribes the first MTIM.

9. The chip package of claim 8, wherein the second MTIM further comprises one or more vent passages operable to allow the first MTIM to outgas through the second MTIM.

10. The chip package of claim 2, wherein the first MTIM is gallium, gallium-based alloy, indium or indium alloy.

11. The chip package of claim 10, wherein the second MTIM is a tin-based material.

12. The chip package of claim 2, wherein the retaining structure comprises:
a thermally conductive ring having a top side and a bottom side; and
a second MTIM disposed at least on one of the bottom side or the top side of the thermally conductive ring.

13. The chip package of claim 12, wherein the thermally conductive ring is a flat copper ring.

14. The chip package of claim 2, wherein the retaining structure comprises:
a thermally conductive ring having a top side and a bottom side;
a second MTIM disposed on the top side of the thermally conductive ring; and
a third MTIM disposed on the bottom side of the thermally conductive ring, the third MTIM having a melting point higher than a melting point of the first MTIM.

15. A chip package comprising:
a substrate;
an integrated circuit (IC) die having a bottom surface facing a top surface of the substrate;
a first metal thermal interface material (MTIM) disposed on a top surface of the IC die;
a lid disposed over the IC die, the lid having a bottom side contacting the first MTIM; and
a retaining structure disposed outwardly of the first MTIM, the retaining structure capturing the first MTIM on the top surface of the IC die, wherein the retaining structure comprises:
a lip disposed outward of and extending around the first MTIM, the lip having at least a first gap; and
a second MTIM between the first MTIM and the first gap, the second MTIM having a melting point higher than a melting point of the first MTIM or comprising a permeable metal material.

16. The chip package of claim 15, wherein the second MTIM is solder or a permeable metal material, and wherein the permeable metal material is a metal foam, a metal mesh, or a metal wool.

17. The chip package of claim 15, wherein the lip extends from the bottom side of the lid.

18. A method for fabricating a chip package comprising:
mounting a lid over an integrated circuit (IC) die disposed on a substrate to form a lidded chip package;
heating the lidded chip package to a first temperature, the first temperature above a melting point of a first metal thermal interface material disposed in contact with a top of the IC die and a bottom side of the lid and below a melting point of a second metal thermal interface material disposed around the first metal thermal interface material, wherein while at the first temperature, outgas generated by the first metal thermal interface material is able to flow across at least one side of the second metal thermal interface material;
heating the lidded chip package to a second temperature above the melting point of the second metal thermal interface material, wherein after being heated to the second temperature, the second metal thermal interface material forming a gas seal around the first metal thermal interface material.

19. The method of claim 18, wherein heating the lidded chip package to the first temperature comprises heating the lidded chip package to at least 160 degrees Celsius, and wherein heating the lidded chip package to the second temperature comprises heating the lidded chip package to at least 250 degrees Celsius.

20. The method of claim 19, wherein after heating lidded chip package to at least 250 degrees Celsius, cooling the heating lidded chip package to a temperature below about 160 degrees Celsius, then heating the heating lidded chip package to reflow solder connecting a bottom of the IC die to a substrate.
